(19) United States
(12) Patent Application Publication
(10) Pub. No.: US 2003/0165208 A1
(43) Pub. Date: Sep. 4, 2003

(54) Non-linear decision feedback phase locked loop filter

(76) Inventors: Andrew Carter, Minneapolis, MN (US); Iain Ross MacTaggart, Eden Prairie, MN (US)

Correspondence Address: SCHWEGMAN, LUNDBERG, WOESSNER & KLUTH, P.A., P.O. BOX 2938, MINNEAPOLIS, MN, 55402, US

(21) Appl. No.: 10/090,435

(22) Filed: Mar. 4, 2002

(51) Int. Cl. H03D 3/24

(52) U.S. Cl. 375/373; 375/376

(57) ABSTRACT

Systems, devices and methods are provided for precisely and responsively compensating for deterministic jitter. One aspect of the present subject matter is a circuit for improving a phase lock of a timing signal for a receiver. One embodiment includes a sample and hold circuit, a decision logic module, and a switch. The sample and hold circuit is adapted to receive and hold a phase signal that represents a signal from a phase detector of the receiver. The switch is adapted to controllably pass the phase signal from the sample and hold circuit. The passed phase signal is capable of being used in adjusting the timing signal for the receiver. The decision logic module is adapted to detect good signal transitions, and actuate the switch to pass the phase signal for good signal transitions. Other aspects are provided herein.

### TECHNICAL FIELD

This invention relates generally to signal processing technology and, more particularly, to phase lock loop circuits for recovering transmission signal timing in digital communication systems.

### BACKGROUND OF THE INVENTION

A communication system generally includes a communication channel, transmitter for transmitting signals through the channel, and a receiver for receiving the signals from the channel. The receiver needs to be able to determine both when the transmission signal should be sensed (i.e. the phase of the transmission signal) and the value of the sensed signal in order to accurately receive the transmission signal. Some systems, such as digital microprocessor-based systems, use a clock signal to accurately control the timing between the transmitter and the receiver. These clock-based systems generally work well over short distances. However, for systems in which a clock signal is not transmitted, the receiver performs a clock and data recovery (CDR) function. The clock recovery portion of the CDR function determines the timing of communication signal transitions, and the data recovery portion of the CDR function determines the value of the signals at appropriate times based on the recovered clock.

The communication channel inherently possesses bandwidth limitations. A band-limited channel disperses or spreads a pulse waveform passing through it. The spreading of the pulse is slight when the bandwidth is much greater than the pulse bandwidth. The spreading of the pulse exceeds a symbol duration and causes signal pulses to overlap when the channel bandwidth is close to the signal bandwidth. This overlapping of signal pulses is referred to as intersymbol interference. Intersymbol interference resists changes in signal states, and resists changes more when a signal remains in one state longer (such as longer strings of “1s” or “0s”, for example). Thus, the transition timing between signal states deviates for the communication signals based on the code transmitted through the channel. This deviation of the signal transition timing is referred to as deterministic jitter. One definition of jitter is a time-varying shift in the instantaneous phase of a modulated signal. Both the impulse response characteristic of the system and the actual transmitted pulse sequence affects jitter.

One known way of dealing with deterministic jitter places an analog loop filter in the received path. The analog loop filter performs an averaging-like function such that the system makes adjustments based on a number of deviations and thus is less responsive to single deviations. One problem with analog loop filters is that the averaging function not only reduces the responsiveness to a single deviation but also slows down the overall response time. That is, analog filters suffer from lack of precision and responsiveness. Another problem with analog loop filters is that the device is linear, and processes noise in the same way as the signal. That is, analog filters are susceptible to noise.

Due to the continued demand to improve signal processing within the band-limiting constraints of communication channels in high speed communication systems, there is a need in the art for systems, devices and methods that precisely and responsively compensate for deterministic jitter so as to improve the receiving capabilities, and thus the effective bandwidth, of high speed digital communication systems.

### SUMMARY OF THE INVENTION

The above mentioned problems are addressed by the present subject matter and will be understood by reading and studying the following specification. The present subject matter provides systems, devices and methods that compensate for deterministic jitter so as to improve the receiving capabilities, and thus the effective bandwidth, of high speed communication systems. A decision directed (i.e. decision feedback) equalizer is employed in the clock recovery phase locked loop filter of a digital receiver device. Charge from a charge pump that represents the detected phase of a transmission signal is placed on the loop filter only during valid or desired data transitions that promote a precise and responsive compensation for deterministic jitter.

One aspect of the present subject matter is a circuit for improving a phase lock of a timing signal for a receiver. One embodiment includes a sample and hold circuit, a decision logic module, and a switch. The sample and hold circuit is adapted to receive and hold a phase signal that represents a signal from a phase detector of the receiver. The switch is adapted to controllably pass the phase signal from the sample and hold circuit. The decision logic module is adapted to detect good signal transitions, and actuate the switch to pass the phase signal for good signal transitions. The passed phase signal is capable of being used in adjusting the timing signal for the receiver.

One aspect of the present subject matter is a receiver for receiving signals from a transmission channel. One embodiment of the receiver includes slicer circuitry and phase locked loop circuitry. The slicer circuitry is adapted to receive a signal transmitted through the transmission channel and determine amplitude levels for symbols in the received signal. The phase locked loop circuitry is adapted to provide a timing signal for use by the slicer circuitry in determining the amplitude levels, detect a phase of the received signal using signal transitions between symbols within the received signal, determine whether the signal transitions are good signal transitions for detecting the phase of the received signal, and adjust a phase of the timing signal using the good signal transitions.

One aspect of the present invention is a method for selecting desirable signal transitions for use in correcting a timing signal for a receiver. According to one embodiment, a signal is received from a transmission channel. The signal has amplitude levels that represent symbols in the signal, and signal transitions that occur between successive symbols. It is determined whether a signal transition is a good transition for determining a phase of the received signal and correcting the timing signal for the receiver. Upon determining that the signal transition is a good transition, the timing signal for the receiver is adjusted using the good signal transition.

These and other aspects, embodiments, advantages, and features will become apparent from the following description of the invention and the referenced drawings.

### BRIEF DESCRIPTION OF THE DRAWINGS

FIG. 1 illustrates one embodiment of a digital communication transmission system.

FIG. 2 illustrates an eye diagram for a pulse amplitude modulated (PAM) system with five amplitude levels (PAM-5).

FIG. 3 illustrates transitions between amplitude levels in a PAM-4 system, and further illustrates zero-crossings in the PAM-4 system.

FIG. 4 illustrates desirable transitions between amplitude levels in a PAM-4 system.

FIG. 5 illustrates one embodiment for selecting desirable transitions for use in correcting a receiver clock phase.

FIG. 6 illustrates one embodiment of a receiver device.

FIG. 7 illustrates one embodiment of a decision feedback equalizer capable of being used in the receiver device of FIG. 6.

FIG. 8 illustrates one embodiment of a decision feedback equalizer and loop filter capable of being used in the receiver device of FIG. 6.

FIG. 9 illustrates one embodiment of a decision logic module capable of being used in the receiver device of FIG. 6.

FIG. 10 illustrates one embodiment of the decision logic module of FIG. 9.

FIG. 11 illustrate one method embodiment for selecting desirable transitions for use in correcting a receiver clock phase.

### DETAILED DESCRIPTION OF THE INVENTION

The following detailed description of the invention refers to the accompanying drawings which show, by way of illustration, specific aspects and embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims, along with the full scope of equivalents to which such claims are entitled.

The present subject matter provides systems, devices and methods that precisely and responsively compensate for deterministic jitter so as to improve the receiving capabilities, and thus the effective bandwidth, of high speed digital communication systems. Signal transitions between transmitted symbols in the transmission signal are evaluated to determine whether they are good for determining a phase of a signal. Those signal transitions that have a small timing deviation are good signal transitions for determining a phase of a signal. A detected phase of a received signal is passed on to a loop filter and voltage controlled oscillator only for good signal transitions. As such, only the signal transitions that accurately represent the detected phase are used in adjusting the phase of the timing signal for the receiver. Thus, the present subject matter precisely and responsively compensates for deterministic jitter.

FIG. 1 illustrates one embodiment of a digital communication transmission system. The illustrated system 100 includes a communication channel 102 capacitively coupled to a transmitter 104 and a receiver 106 such that the transmitter is capable of transmitting signals to the receiver through the channel. The illustrated embodiment of the system 100 also includes an encoder 108 connected to the transmitter 104 and a decoder 110 connected to the receiver 106. The encoder 108 encodes information into symbols. The transmitter 104 transmits symbols through the transmission channel 102. For example, in a pulse amplitude modulated (PAM) system, the encoder 108 encodes information as various symbols. The transmitter 104 sequentially transmits the symbols as a series of pulses with amplitude levels that represent the symbols. The receiver in the PAM system detects symbols from the amplitude modulated pulses, and the decoder 110 decodes these symbols to receive the original information.

The communication channel 102 inherently possesses bandwidth limitations. A band-limited channel disperses or spreads a pulse waveform passing through it. The spreading of the pulse is slight when the bandwidth is much greater than the pulse bandwidth. The spreading exceeds a symbol duration and causes signal pulses to overlap when the channel bandwidth is close to the signal bandwidth. This overlapping of signal pulses is referred to as intersymbol interference. Intersymbol interference resists changes in signal states, and resists changes more when a signal remains in one state longer (such as longer strings of“1s” or “0s”, for example). Thus, the transition timing between signal states deviates for the communication signals based on the code transmitted through the channel. This deviation in signal transition timing is referred to as deterministic jitter. One definition of jitter is a time-varying shift in the instantaneous phase of a modulated signal. Both the impulse response characteristic of the system and the actual transmitted pulse sequence affects jitter.

Intersymbol interference is described below for one example of a communication system which transmits one bit at a time by varying the amplitude of the signal between two amplitude levels. These two levels may be characterized as a logic 0 and a logic 1. A communication signal “010101” is not effected by intersymbol interference as much as the communication signal “111100.” For example, the transition from the fourth-bit 1 to the fifth-bit 0 in the “010101” signal is quicker than the transition from the fourth-bit 1 to the fifth-bit 0 in the “111100” signal because the “111100” signal has been in the 1 state longer than the “010101” signal. Some known decision feedback equalizers attempt to compensate for the longer transition times attributable to intersymbol interference by anticipating the changing amplitude levels based on the sensed signal and previous pulse values. That is, for example, if a long string of logic 1 pulses is received, the decision feedback equalizer effectively lowers the threshold required (i.e. does not require as big of a transition) to transition from the logic 1 to logic 0 state. The transition threshold is lowered as the string of logic 1 pulses (or string of logic 0 pulses) becomes longer.

Another example of a communication system is a pulse amplitude modulation system (PAM) in which one of M allowable amplitude levels are assigned to each of M possible symbol values. PAM-4, for example, transmits a two bit symbol (b₁, b₀) using four amplitude levels. In a PAM-4 system, a first one of the amplitude levels is assigned the symbol value 00, a second one of the amplitude levels is assigned the symbol value 01, a third one of the amplitude levels is assigned the symbol value 10, and a fourth one of the amplitude levels is assigned the symbol value 11. For example, a PAM-4 system is capable of using two negative voltages and two positive voltages as the four amplitude levels. For example, −3V (00), −1V (01), +1V (10) and +3V (11) are capable of forming the four levels for a PAM-4 system. The communication signal in a PAM-4 system is capable of making transitions from and to any of these four levels. The bandwidth limitations described above causes the transition timing between these four signal states to deviate (i.e. causes deterministic jitter).

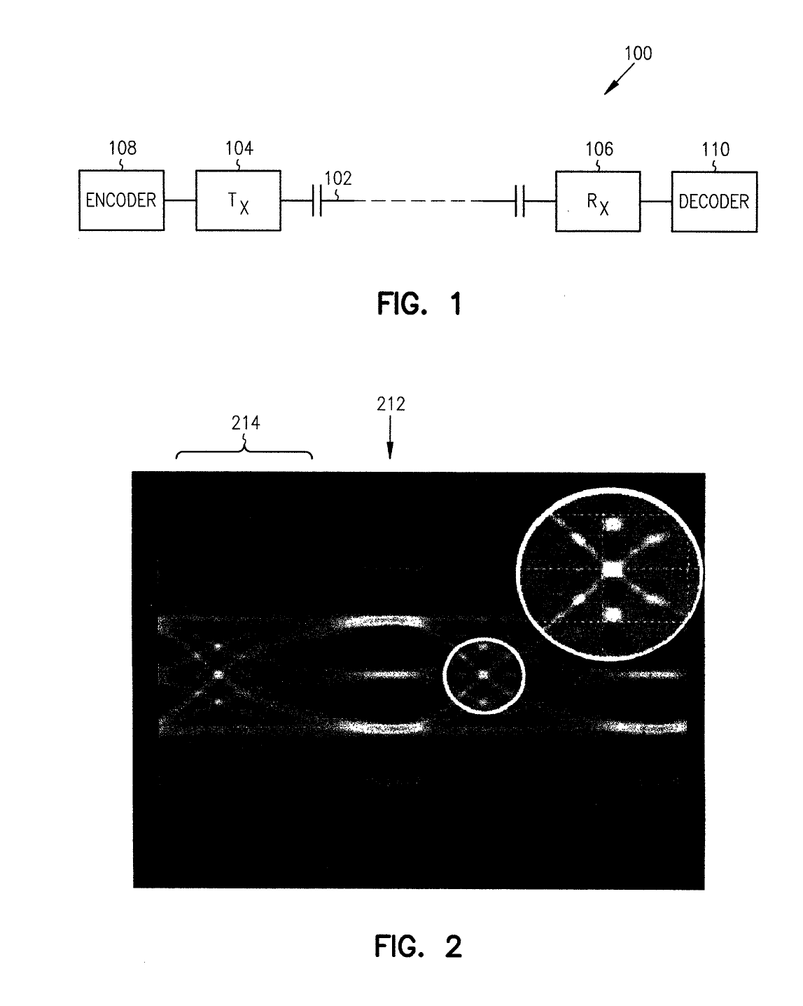

FIG. 2 illustrates an eye diagram for a pulse amplitude modulated (PAM) system with five amplitude levels (PAM-5). The 5 amplitude levels are illustrated as −0.6V, −0.3V. 0.0V, 0.3V and 0.6V. A PAM 5 system is capable of sending 2-bit signals with added headroom for additional coding such control words. Eye diagrams, or eye patterns, are useful tools for viewing deterministic jitter. An eye pattern is a display that results from measuring a system's response to baseband signals using random pulse signals. The various random patterns in the eye pattern illustrate the various transitions between amplitude levels for various bit patterns. The width of the opening 212 indicates the time over which sampling for amplitude detection might be performed. However, a preferred sampling time for amplitude detection corresponds to the maximum eye opening, which yields the greatest protection against noise. Deterministic jitter (or deterministic noise) 214 is represented by the width between successive eye openings.

It is noted that the preferred sampling time for amplitude detection is approximately 90° (or −90° depending on the reference) out of phase with respect to the preferred timing for sampling zero-crossings during the signal transitions for phase detection. The preferred timing also can be considered to be an ideal sample point for detecting phase. Bandwidth limitations cause zero-crossings to deviate with respect to a preferred sample point. The affects of this bandwidth limitation is stochastic as it involves probability. The statistics of this type of interference are dependant on the data pattern and are therefore called deterministic jitter. Broadly speaking, some patterns cause a greater timing deviation from an ideal sampling point than other transitions.

More particularly, FIG. 2 shows the eye diagram for a 5 Gigabaud PAM-5 data signal running over a band-limited copper channel. Overall, deterministic jitter reaches nearly 50% for the illustrated system. However, if only certain transitions are examined, the total deterministic jitter is capable of being reduced to roughly 1%. In this figure, the bright dot in the middle of the breakout shows the zero crossings of the much reduced transition set. That is, the bright dot is attributable to a number of signal transitions, that is a relatively small proportion to the overall number of signal transitions, that have zero crossings with very little timing deviation.

Therefore, as is described in detail below with respect to FIGS. 6, 9 and 10, decision logic is provided in one embodiment of the phase locked loop filter such that the charge pump is allowed to place charge on the loop filter for use by the voltage controlled oscillator only when desirable transitions occur. Desirable transitions are those transitions that cause a zero crossing near the ideal sampling point and therefore, reduce the spread of a zero crossing histogram.

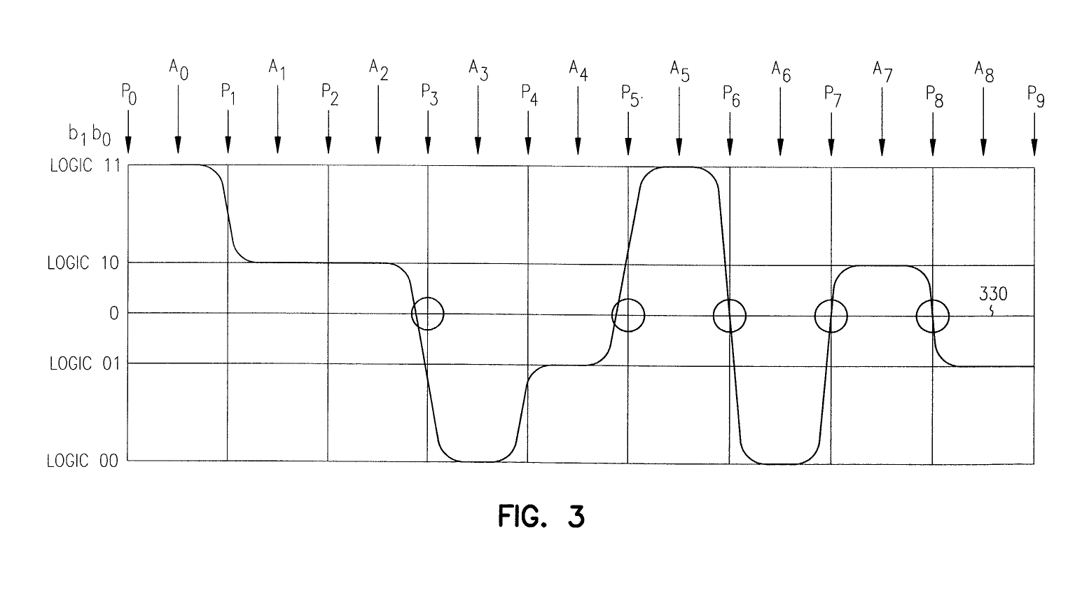

The concepts of zero crossing and desirable transitions have been introduced above with respect to the eye diagram of FIG. 2. These concepts are further developed below with respect to FIGS. 3-5.

FIG. 3 illustrates transitions between amplitude levels in a PAM-4 system, and further illustrates zero-crossings in the PAM-4 system. The PAM-4 system, by definition, encodes information into symbols using four amplitude levels. In one embodiment, these amplitude levels are positioned symmetrically about the 0 axis 330. A PAM-4 system is capable of encoding and transmitting two bits (b₀ and b₁) in each transmitted symbol. As such, the amplitude levels include a logic 00 level, a logic 01 level, a logic 10 level, and a logic 11 level. One of ordinary skill in the art will understand that these logic values for these bits are capable of being assigned to the various amplitude levels in a number of different ways. FIG. 3 shows these logic values assigned to the amplitude levels in an ascending order from bottom to top. The invention is not so limited.

The vertical lines in FIG. 3 represent preferred phase detection times (represented as P₀-P₉). In this illustration, one cycle extends from P₀ to P₂ such that P₀ and P₁ are 180° apart. These phase detection times are 90°, or approximately 90°, out of phase with respect to preferred amplitude level detection times (represented as A₀-A₈). The overall waveform is referred to as a signal. Amplitude levels between successive phase detection times are referred to as symbols. Each symbol represents a logic value for two bits (b₀ and b₁). The sequence of pulse waveforms in the signal represents the following sequence of symbols (from A₀ to A₈): 11, 10, 10, 00, 01, 11, 00, 10 and 01. The transition between these amplitude levels, if any, occur near the phase detection times (P₀-P₉). In one embodiment, a phase detector in a receiver, such as receiver 106 in FIG. 1, detects zero crossings in the signal. A zero crossing is a point in the signal in which the signal transitions from a negative to a positive value or from a positive to a negative value. One of ordinary skill in the art will understand, upon reading and understanding this disclosure, that amplitude levels are capable of being offset such that an “effective zero crossing” occurs at a non-zero amplitude level, and that a non-zero reference voltage is capable of being used to detect the “effective zero crossing.” Zero crossings are encircled in FIG. 3. The phase detector uses these zero crossings to determine a phase of the signal. However, as illustrated in FIG. 3, some zero crossings occur closer to their corresponding phase detection time than other zero crossings. For example, the zero crossings that occur near the phase detection times P₃, P₅ and P₇ deviate more than the zero crossings that occur near the phase detection times P₆ and P₈. Both the severity and the probability of deviation are capable of being represented by a histogram. This deviation is also represented by the deterministic jitter that occurs between the eyes in the eye diagram of FIG. 2. Desirable transitions, or good signal transitions, are those transitions which have smaller deviation times from their corresponding phase detection time.

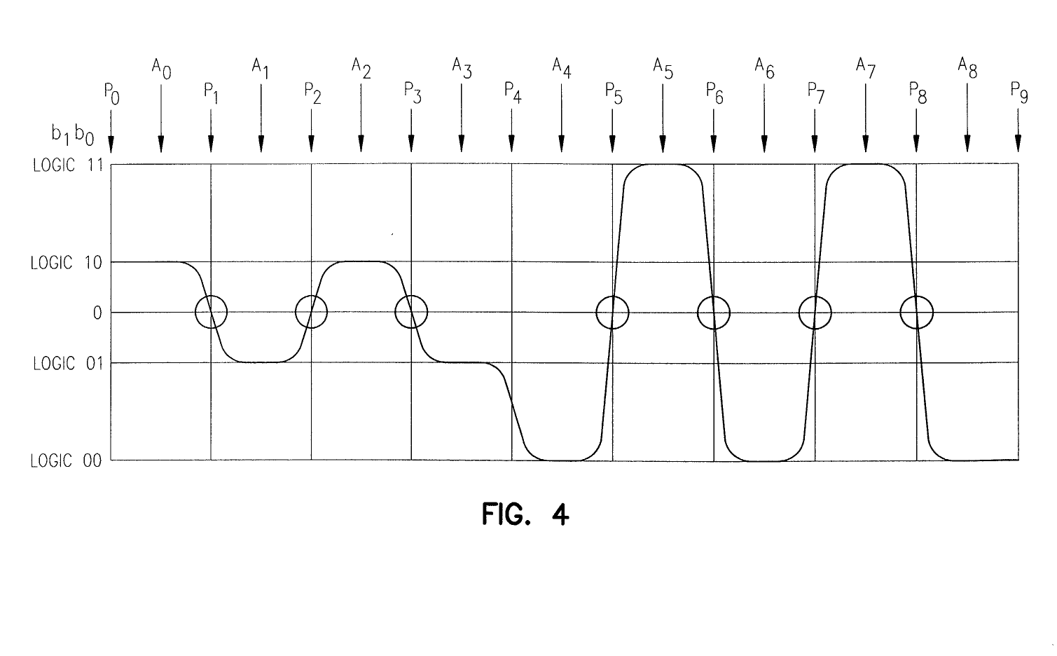

FIG. 4 illustrates desirable transitions between amplitude levels in a PAM-4 system. It is noted that good signal transitions occur across symmetrical transitions between amplitude levels. For example, the zero crossing for the transition at P₁ from logic 10 at A₀ to logic 01 at A₁ deviates very little from the corresponding phase detection time P₁. The zero crossing for the transition P₂ from logic 01 at A₁ to logic 10 at A₂ also deviates very little from the corresponding phase detection time P₂. Furthermore, the zero crossing for the transition at P₆ from logic 11 at A₁ to logic 00 at A₆ deviates very little from the corresponding phase detection time P₆; and the zero crossing for the transition P₇ from logic 00 at A₆ to logic 11 at A₇ also deviates very little from the corresponding phase detection time P₇.

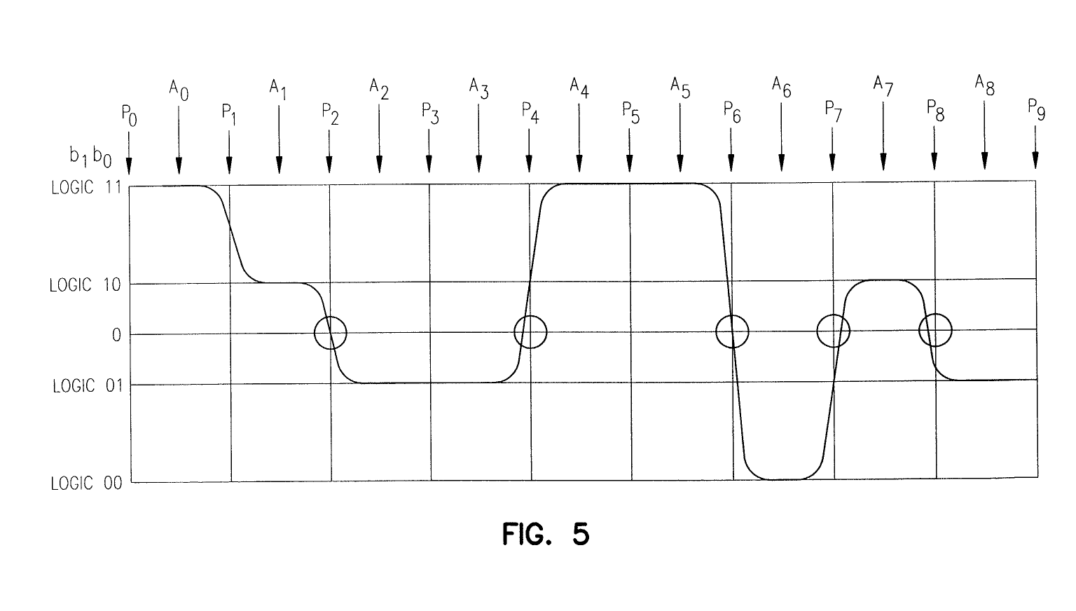

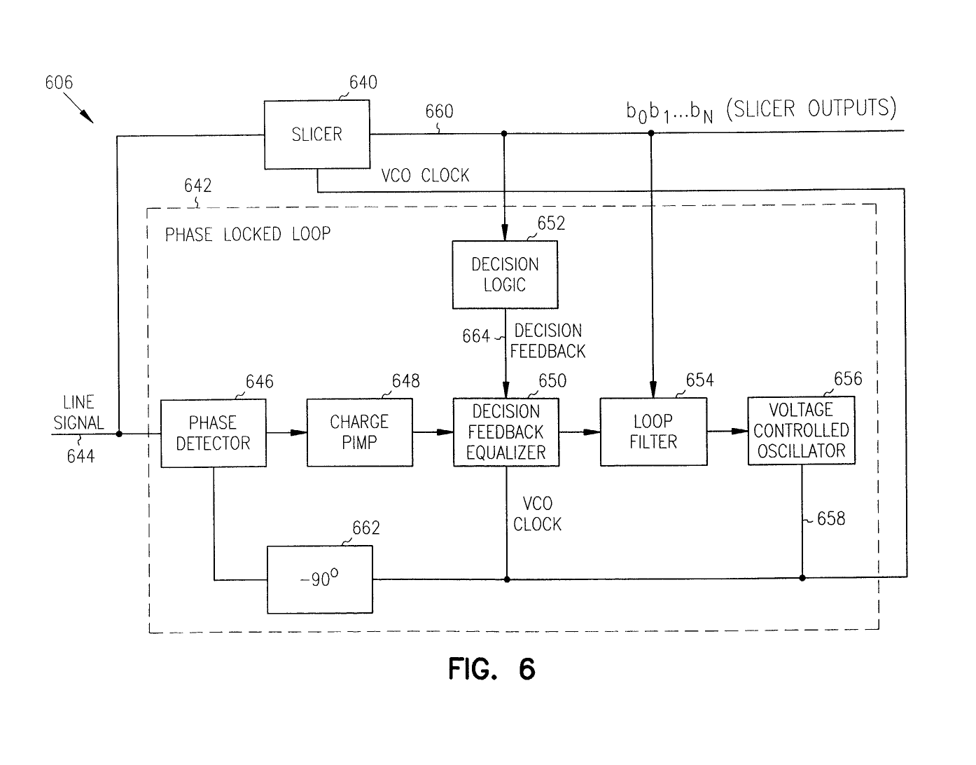

FIG. 5 illustrates one embodiment for selecting desirable transitions for use in correcting a receiver clock phase. The illustrated signal begins at P₀. The transition at P₁ is not a zero crossing, and as such is ignored by the phase detector. The transition at P₂ is a symmetrical zero crossing, and is deemed as a good signal transition from logic 10 at A₁ to logic 01 at A₂. The transition at P₃ is not a zero crossing, and as such is ignored by the phase detector. The transition at P₄ is a zero crossing, but is not deemed to be a good signal transition because of the larger deviation from the corresponding phase detection time P₄. The transition at P₅ is not a zero crossing, and as such is ignored by the phase detector. The transition at P₆ is a symmetrical zero crossing, and is deemed as a good signal transition from logic 11 at A₅ to logic 00 at A₆. The transition at P₇ is a zero crossing, but is not deemed to be a good signal transition because of the larger deviation from the corresponding phase detection time P₇. The transition at P₈ is a symmetrical zero crossing, and is deemed as a good signal transition from logic 10 at A₇ to logic 01 at A₈. As such, precise zero crossings are provided at P₂, P₆ and P₈. These precise zero crossings are capable of being used to precisely control a voltage control oscillator, and improve a phase lock of a timing signal for a receiver. Furthermore, by only using good transitions, such as those with precise zero crossings, the present subject matter improves the responsiveness and efficiency for locking the phase of the timing signal.

FIG. 6 illustrates one embodiment of a receiver device. The illustrated receiver device 606 generally includes slicer circuitry 640 and phase locked loop circuitry 642, both of which are capable of receiving a line signal from the transmission line at 644. The phase locked loop circuitry 642 generally includes a phase detector 646, a charge pump 648, a decision feedback equalizer 650 that receives feedback from a decision logic module 652, a loop filter 654, and a voltage controlled oscillator (VCO) 656 that generally provides and controls a timing signal (VCO clock) 658 that functions as a receiver clock.

The slicer circuitry 640, as is known to one of ordinary skill in the art, performs the data recovery portion of a CDR function by receiving an incoming line signal and determining the amplitude levels for the various symbols contained in the line signal. The slicer circuitry 640 is capable of providing four outputs 660, such as in a PAM-4 system, or another number of outputs according to the design and requirements of the communication system. The slicer circuitry determines the amplitude levels around times A₀, A₁, A₂, etc. as generally illustrated in FIGS. 3-5. The timing for the slicer circuitry 640 is controlled by the VCO clock 658.

The phase locked loop circuitry 642 performs the clock recovery portion of a CDR function by receiving an incoming line signal, determining the phase of the transmission, and locking the phase of the receiver clock to the phase of the transmission. The phase detector 646, as is known to one of ordinary skill in the art, detects transitions between symbols within the incoming line signal. One phase detector embodiment detects transitions by detecting zero crossings in the signal. The timing of the phase detector 646 is controlled by the VCO clock 658. However, as is represented at 662, the VCO clock is shifted approximately 90°. This is generally represented by the approximately 90° offset between the amplitude level detection times (A₀-A₈) and the phase detection times (P₀-P₉) in FIGS. 3-5. In one embodiment, a charge pump 646 is included to strengthen or amplify a phase signal from the phase detector 646 that represents the phase of the line signal. In one embodiment, the phase signal from the phase detector 646 that represents the phase of the line signal is a voltage level that represents a voltage at a phase detection time, and thus represents a deviation from the zero crossing.

The decision logic module 652 provides a decision feedback signal 664 based on the values of the slicer outputs. In effect, the specific logic within the decision logic module 652 determines what constitutes a good signal transition for detecting the phase of the received line signal. In response to a good signal transition as detected by the decision logic module, the decision feedback equalizer circuitry 650 passes the phase signal from the charge pump 648 to the loop filter 654.

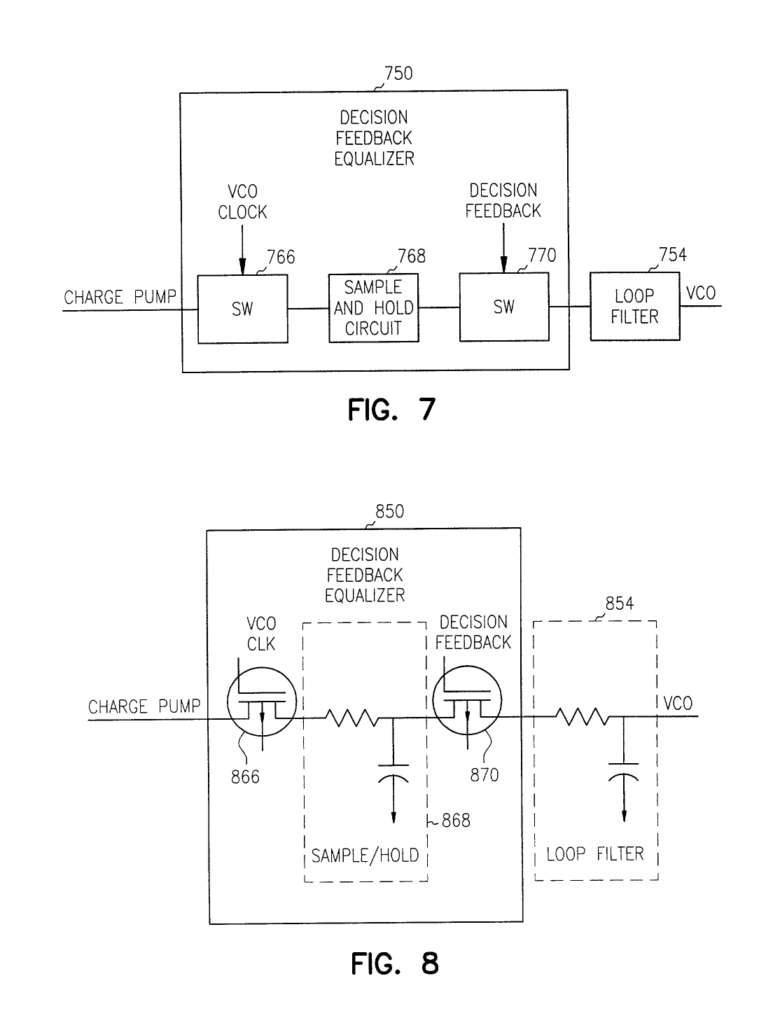

FIG. 7 illustrates one embodiment of a decision feedback equalizer 750 capable of being used in the receiver device of FIG. 6. According to one embodiment, the VCO clock is used to clock a switch 766 that gates a sample and hold circuit 768. That is, in this embodiment, the representative phase signal provided by the charge pump is stored in the sample and hold circuit for every VCO clock cycle, which can be viewed generally as the amplitude level detection times A₀, A₁, A₂, etc. in FIGS. 3-5. According to this embodiment, this voltage is held until the data sample before the held phase sample and the data sample after the held phase sample have been processed. A decision feedback signal actuates a switch 770 to allow the voltage to pass to the loop filter for good signal transitions. If these two data samples are considered “correct” by the updating algorithm, the held phase sample is then allowed to be passed to the loop filter. For example, if two concurrent bits are the same level, the decision feed back logic does not allow the charge pump to pass current to the loop filter.

FIG. 8 illustrates one embodiment of a decision feedback equalizer 850 and loop filter 854 capable of being used in the receiver device of FIG. 6. In this embodiment, both the sample and hold circuit 8668 and the loop filter 854 are represented as resistor-capacitor networks for storing charge. The switches 866 and 870 are illustrated as field effect transistors (FETs). The gate of the first FET 866 is connected to the VCO clock, and the gate of the second FET 870 is connected to the decision feedback line. The illustrated FETs are N-type FETs such that a positive voltage at the gate with respect to the source will allow a current to flow through the FET. One of ordinary skill will understand that the invention is not limited to N-type FETs, or to field effect transistors in general.

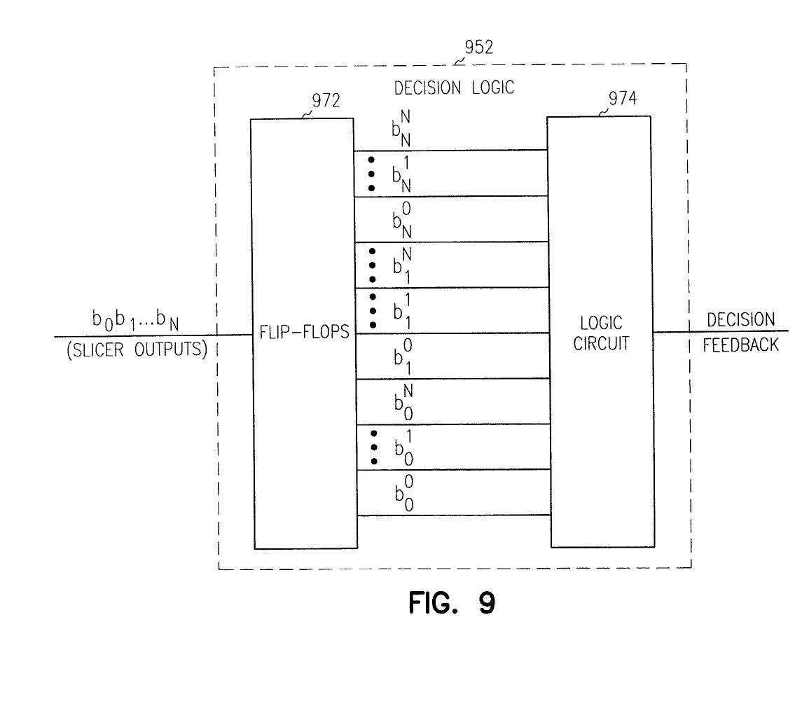

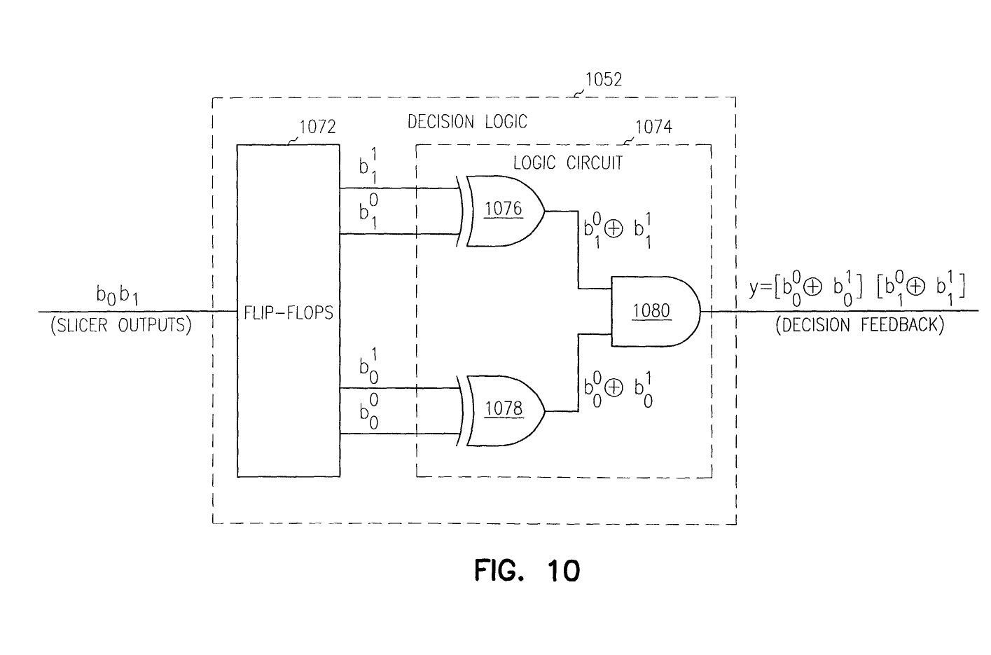

FIG. 9 illustrates one embodiment of a decision logic module capable of being used in the receiver device of FIG. 6. The decision logic module 952 is connected to the slicer outputs, which are capable of transmitting a series of symbols (b⁰, b¹ . . . bⁿ), with each symbol representing a number of bits (b₀, b₁ . . . bₙ) sent every baud. In this embodiment, the decision logic module 952 includes flip-flops 972 for latching or holding onto a number of successive symbols. Each of these symbols represents a logic value for a number of bits. The symbols in a PAM-4 system, for example, represent logic values for 2 bits. The invention is not so limited, however. In this embodiment, the decision logic module 952 further includes a logic circuit 974 to receive the first bits of the n latched symbols

$$( {b}_{0}^{0} , {b}_{0}^{1} … {b}_{0}^{n} ) ,$$

the second bits of the n latched symbols

$$( {b}_{n}^{0} , {b}_{n}^{1} … {b}_{n}^{n} ) .$$

and the n bits of the n latched symbols

$$( {b}_{1}^{0} , {b}_{1}^{1} … {b}_{1}^{n} ) ,$$

The logic circuit contains appropriate logic to identify whether a transition is a good signal transition for detecting a signal phase. The result of the logic operation performed by the logic circuit is provided on the decision feedback line to provide feedback to the decision feedback equalizer.

FIG. 10 illustrates one embodiment of the decision logic module of FIG. 9. The illustrated logic circuit 1074 includes Exclusive-Or gates 1076 and 1078 and an And gate 1080. The outputs of the Exclusive-Or gates are connected to the inputs of the And gate to provide the logic function as shown in the figure. In a PAM-4 system, two bits (b₀ and b₁) are sent every baud. A signal for such a PAM-4 system is generally illustrated in FIGS. 3-5. These bits are recorded on either side of a sampling time of a phase. The phase sample value is fed onto a sample and hold capacitor. Logic examines the values of

$${b}_{0}^{0} and {b}_{0}^{1}$$

(two consecutive values of bit b₀) and b₁⁰ and b₁¹ (two consecutive values of bit b₁) collectively. The result of the logic equation opens a MOS transistor which allows the phase sampled data to flow on the phase locked loop filter. According to one embodiment, the MOS transistor is opened by the logic equation:

$$y = [ {b}_{0}^{0} ⊕ {b}_{0}^{1} ] \cdot [ {b}_{1}^{0} ⊕ {b}_{1}^{1} ] .$$

Table 1 illustrates a truth table of this equation for all possible values of b₀ and b₁.

TABLE 1

| b₀⁰ | b₀¹ | b₁⁰ | b₁¹ | y |
|---|---|---|---|---|
| 0 | 0 | 0 | 0 | 0 |
| 0 | 0 | 0 | 1 | 0 |
| 0 | 0 | 1 | 0 | 0 |
| 0 | 0 | 1 | 1 | 0 |
| 0 | 1 | 0 | 0 | 0 |
| 0 | 1 | 0 | 1 | 1 |
| 0 | 1 | 1 | 0 | 1 |
| 0 | 1 | 1 | 1 | 0 |
| 1 | 0 | 0 | 0 | 0 |
| 1 | 0 | 0 | 1 | 1 |
| 1 | 0 | 1 | 0 | 1 |
| 1 | 0 | 1 | 1 | 0 |
| 1 | 1 | 0 | 0 | 0 |
| 1 | 1 | 0 | 1 | 0 |
| 1 | 1 | 1 | 0 | 0 |
| 1 | 1 | 1 | 1 | 0 |

It is noted that, when the amplitude levels are assigned the various logic values in descending or ascending sequence and when the amplitude levels are centered about the 0 axis, one embodiment of the decision logic module determines that a good signal transition occurred if all of the bits in the symbol have toggled. When the amplitude levels are assigned as described above, a signal transition in which all of the bits in the symbol have been toggled is a symmetric transition about the 0 axis. These symmetric transitions have precise zero crossings, and are good transitions for accurately determining the phase of the signal.

The figures presented and described in detail above are similarly useful in describing the method aspects of the present subject matter. The methods described below are nonexclusive as other methods may be understood from the specification and the figures described above.

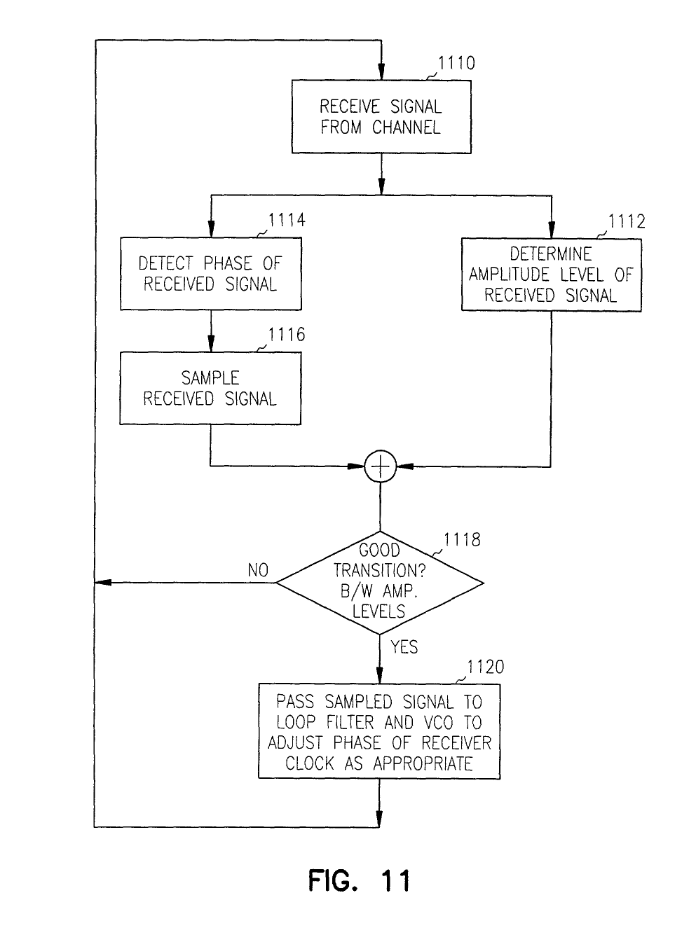

FIG. 11 illustrate one method embodiment for selecting desirable transitions for use in correcting a receiver clock phase. A transmission is received from a transmission channel at 1110. As previously seen in FIG. 6, slicer circuitry and phase locked loop circuitry operate on the received signal. The amplitude level that represents the logic value or symbol of the received signal is determined at 1112. According to one embodiment, the logic values for a number of symbols are stored and compared for use in determining signal transitions. At 1114, the phase of the received signal is detected. A representative sample of the received signal is taken at 1116. This representative sample corresponds to the phase of the received signal. At 1118, it is determined whether there has been a good transition between the amplitude levels. A signal transition is a good transition when the phase is capable of being accurately determined. Upon determining that a good transition has occurred, the process proceeds to 1120, where the sampled signal is passed to a loop filter and voltage controlled oscillator, for example, for use in appropriately adjusting the phase of a receiver clock. Upon determining that a good transition has not occurred, the sampled signal is discarded and the process returns to 1110 to continue to process the various symbols in the received signal.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. It is to be understood that the above description is intended to be illustrative, and not restrictive. Combinations of the above embodiments, and other embodiments will be apparent to those of skill in the art upon reviewing the above description. The scope of the invention includes any other applications in which the above structures and fabrication methods are used. The scope of the invention should be determined with reference to the appended claims, along with the full scope of equivalents to which such claims are entitled.

What is claimed is:

1. A circuit for improving a phase lock of a timing signal for a receiver, comprising:
a sample and hold circuit adapted to receive and hold a phase signal that represents a signal from a phase detector of the receiver;
a switch connected to the sample and hold circuit and adapted to controllably pass the phase signal from the sample and hold circuit for use in adjusting the timing signal for the receiver; and
a decision logic module operably connected to the switch, wherein the decision logic module is adapted to:
detect good signal transitions; and
actuate the switch for good signal transitions such that the phase signal is passed from the sample and hold circuit for use in adjusting the timing signal for the receiver.

2. The circuit of claim 1, wherein the decision logic module is adapted to detect signal transitions that have zero crossings that deviate from a phase sampling time less than zero crossings for other signal transitions.

3. The circuit of claim 1, wherein:
the decision logic module includes an input adapted to receive slicer output signals;
the decision logic module is adapted to detect good signal transitions based on the slicer output signals;
the slicer output signals provide logic values for at least two bits; and
the decision logic module is adapted to detect signal transitions between logic values that toggles each of the at least two bits.

4. The circuit of claim 1, wherein:
the decision logic module includes an input adapted to receive slicer output signals;
the decision logic module is adapted to detect good signal transitions based on the slicer output signals;
the slicer output provides a logic value for a first bit b₀ and a second bit b₁;
the decision logic module includes:
flip-flop circuitry for holding logic values from the slicer output signals for a first symbol and a successive second symbol, wherein b₀⁰ and b₁⁰ represent the first bit and the second bit for the first symbol, and b₀¹ and b₁ ¹ represent the first bit and the second bit for the second symbol; and
logic circuitry connected to the flip-flop circuitry and adapted to provide an output Y to actuate the switch to pass the phase signal from the sample and hold circuit for use in adjusting the timing signal for the receiver, wherein
$$Y = [ {b}_{0}^{0} ⊕ {b}_{0}^{1} ] \cdot [ {b}_{1}^{0} ⊕ {b}_{1}^{1} ] .$$

5. The circuit of claim 1, further comprising a sampling switch connected to the sample and hold circuit, the sampling switch being adapted to controllably pass the phase signal to the sample and hold circuit, wherein the timing signal for the receiver controllably actuates the sampling switch to pass the phase signal to the sample and hold circuit.

6. A receiver for receiving signals from a transmission channel, comprising:
slicer circuitry adapted to receive a signal transmitted through the transmission channel and determine amplitude levels for symbols in the received signal; and
phase locked loop circuitry adapted to:
provide a timing signal for use by the slicer circuitry in determining the amplitude levels for symbols;
detect a phase of the received signal using signal transitions within the received signal;
determine whether the signal transitions are good signal transitions for detecting the phase of the received signal; and
adjust a phase of the timing signal using the good signal transitions.

7. The receiver of claim 6, wherein the slicer circuitry is adapted to receive pulse amplitude modulated (PAM) signals for at least four amplitude levels.

8. The receiver of claim 6, wherein the phase locked loop circuitry includes a decision logic module adapted to determine whether the amplitude levels determined by the slicer circuitry represent good signal transitions for detecting the phase of the received signals.

9. The receiver of claim 6, wherein the decision logic module is adapted to detect signal transitions that have zero crossings that deviate from a phase sampling time less than zero crossings for other signal transitions.

10. The receiver of claim 6, wherein:
the amplitude levels from the received signals represent logic values for at least two bits; and
the decision logic module is adapted to detect signal transitions between logic values that toggles each of the at least two bits.

11. The receiver of claim 10, wherein:
the amplitude levels determined by the slicer circuitry represent a logic value for a first bit b₀ and a second bit b₁;
the decision logic module includes:
flip-flop circuitry for holding logic values for a first symbol and a successive second symbol, wherein b₀⁰ and b₁⁰ represent the first bit and the second bit for the first symbol, and b₀¹ and b₁¹ represent the first bit and the second bit for the second symbol; and
logic circuitry connected to the flip-flop circuitry and adapted to provide an output Y to be used to adjust a phase of the timing signal using the good signal transitions, wherein
$$Y = [ {b}_{0}^{0} ⊕ {b}_{0}^{1} ] \cdot [ {b}_{1}^{0} ⊕ {b}_{1}^{1} ] .$$

12. The receiver of claim 6, wherein the phase locked loop circuitry includes a decision feedback equalizer, including:
a sample and hold circuit adapted to receive and hold a phase signal that represents the phase of the received signal; and
a switch connected to the sample and hold circuit and adapted to controllably pass the phase signal for good signal transitions from the sample and hold circuit for use in adjusting the phase of the timing signal.

13. A receiver for receiving signals transmitted through a transmission channel, comprising:
slicer circuitry adapted to determine amplitude levels for symbols within a received signal, the slicer circuitry including a slicer output for providing the amplitude levels for the symbols; and
phase locked loop circuitry, including:
a voltage controlled oscillator adapted to provide a timing signal for the slicer circuitry to determine the amplitude levels;
a phase detector adapted to detect signal transitions and provide a phase signal that represents a signal phase for the received signal;
a decision logic module connected to the slicer output and adapted to provide a decision feedback output that indicates whether the amplitude levels represent good signal transitions for detecting the phase of the received signal; and
a decision feedback equalizer adapted to receive the decision feedback output, and pass the phase signal for a good signal transition such that only good signal transitions are used by the voltage controlled oscillator in adjusting the timing signal for the slicer circuitry.

14. The receiver of claim 13, wherein the slicer circuitry is adapted to receive pulse amplitude modulated (PAM) signals for at least four amplitude levels.

15. The receiver of claim 13, wherein the decision logic module includes:
flip-flop circuitry for holding logic values for a first symbol and a successive second symbol, wherein b₀⁰ and b₁⁰ represent a first bit and a second bit for the first symbol, and b₀¹ and b₁¹ represent a first bit and a second bit for the second symbol; and
logic circuitry connected to the flip-flop circuitry and adapted to provide an output Y to be used to adjust a phase of the timing signal using the good signal transitions, wherein
$$Y = [ {b}_{0}^{0} ⊕ {b}_{0}^{1} ] \cdot [ {b}_{1}^{0} ⊕ {b}_{1}^{1} ] .$$

16. The receiver of claim 13, wherein decision feedback equalizer includes:
a sample and hold circuit adapted to receive and hold a phase signal that represents the phase of the received signal; and
a switch connected to the sample and hold circuit and adapted to controllably pass the phase signal for good signal transitions from the sample and hold circuit for use in adjusting the phase of the timing signal.

17. A method for selecting desirable signal transitions for use in correcting a timing signal for a receiver, comprising:
receiving a signal from a transmission channel, wherein the received signal has symbol pulses with predetermined amplitude levels and signal transitions occur between successive symbol pulses;
determining whether a signal transition is a good transition for determining a phase of the received signal and correcting the timing signal for the receiver;
upon determining that the signal transition is a good transition, adjusting the timing signal for the receiver using the good transition.

18. The method of claim 17, wherein determining whether a signal transition is a good transition includes determining whether the transition from a first amplitude level to a second amplitude level is symmetrical about a zero-crossing.

19. The method of claim 17, wherein:
each of the symbol pulses includes a logic value for N bits in a pulse amplitude modulated system; and
determining whether a signal transition is a good transition includes determining whether each of the N bits has been toggled during the transition.

20. The method of claim 17, wherein:
each of the symbol pulses includes a logic value for a first bit and a second bit in a pulse amplitude modulated system;
b₀⁰ and b₁⁰ represent the first bit and the second bit for a first symbol pulse;
b₀¹ and b₁¹ represent the first bit and the second bit for a second symbol pulse;
determining whether a signal transition is a good transition includes determining whether a logic output Y is 1, wherein
$$Y = [ {b}_{0}^{0} ⊕ {b}_{0}^{1} ] \cdot [ {b}_{1}^{0} ⊕ {b}_{1}^{1} ] .$$

21. A method for selecting desirable signal transitions for use in correcting a timing signal for a receiver, comprising:
receiving a first symbol pulse and a second symbol pulse from a transmission channel, wherein the first symbol pulse and the second symbol pulse have amplitude levels, and wherein a signal transition occurs between the first symbol pulse and the second symbol pulse;
detecting a signal phase for one of the first symbol pulse and the second symbol pulse using the signal transition and the timing signal for the receiver;
sampling a signal that represents the signal phase using the timing signal for the receiver;
determining amplitude levels for the first symbol pulse and the second symbol pulse;
determining whether the signal transition between the amplitude levels for the first and second symbol pulses is a good transition for determining the signal phase and correcting the timing signal for the receiver; and
upon determining that the signal transition is a good transition, passing the sampled signal that represents the signal phase to a loop filter and a voltage controlled oscillator for use in adjusting the timing signal for the receiver.

22. The method of claim 21, wherein determining whether the signal transition between the amplitude levels for the first and second symbol pulses is a good transition includes determining whether the signal transition for the detected signal phase has a zero crossing near a phase sampling time that is controlled by the timing signal for the receiver.

23. The method of claim 21, wherein determining whether the signal transition between the amplitude levels for the first and second symbol pulses is a good transition includes determining whether the signal transition is symmetrical about a zero-crossing.

24. The method of claim 21, wherein:
each of the first and second received symbol pulses includes a logic value for N bits in a pulse amplitude modulated system; and
determining whether the signal transition between the amplitude levels for the first and second signals is a good transition includes determining whether each of the N bits has been toggled during the transition.

25. The method of claim 21, wherein:
each of the first and second received symbol pulses include a logic value for 2 bits in a pulse amplitude modulated system;
$${b}_{0}^{0} and {b}_{1}^{0}$$
represent the first bit and the second bit for a first symbol pulse;
b₀¹ and b₁¹ represent the first bit and the second bit for the second symbol pulse;
determining whether the signal transition between the amplitude levels for the first and second symbol pulses is a good transition includes determining whether a logic output Y is 1, wherein
$$Y = [ {b}_{0}^{0} ⊕ {b}_{0}^{1} ] \cdot [ {b}_{1}^{0} ⊕ {b}_{1}^{1} ] .$$

26. The method of claim 21, wherein passing the sampled signal includes actuating a switch to pass the sampled signal from a sample and hold circuit to the loop filter and the voltage controlled oscillator using a decision feedback signal that indicates that the signal transition between the amplitude levels for the first and second symbol pulses is a good transition.
